(19) United States
(12) Patent Application Publication
(10) Pub. No.: US 2024/0357764 A1
(43) Pub. Date: Oct. 24, 2024

(54) PREFABRICATED DATA CENTER COMPUTER ROOM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/635,890

(22) Filed: Apr. 15, 2024

(30) Foreign Application Priority Data
Apr. 21, 2023 (CN) 202310433537.6

(51) Int. Cl. H05K 7/14; E04B 1/348

(52) U.S. Cl. CPC H05K 7/1497; E04B 1/34869

(57) ABSTRACT

The present disclosure discloses a prefabricated data center computer room, including a modular cabinet and a modular channel. The modular channel includes a frame body including a first frame and a second frame, where a preset distance is provided between the first frame and the second frame to form a hot channel. The first frame and the second frame both have a truss structure, and certain spacing is provided between the truss structure and a bottom of the frame body to form a containment area. A plurality of the modular cabinets are provided and arranged side by side in the containment area, which is further internally provided with a guide component. When the modular cabinet comes into contact with the guide component, the guide component provides a friction force to the modular cabinet, such that the modular cabinet moves along the guide component.

### CROSS REFERENCE TO RELATED APPLICATION

This application claims priority to Chinese Patent Application No. 202310433537.6, titled “PREFABRICATED DATA CENTER COMPUTER ROOM” and filed to the China National Intellectual Property Administration on Apr. 21, 2023, the entire contents of which are incorporated herein by reference.

### TECHNICAL FIELD

The present disclosure relates to the technical field of data center computer room, and more particularly, to a prefabricated data center computer room.

### BACKGROUND

In the era of rapid development of national informatization and digitization, data center computer rooms have become an important part of national economic development. With the scale expansion of data centers and the large-scale use of high-power density servers, heat production of a single cabinet has increased sharply. Therefore, it is required to plan internal airflow reasonably, thereby improving return air efficiency of air conditioners, and achieving effects of energy conservation and consumption reduction.

At present, most of the data center computer rooms are mainly equipped with sealed hot channels. However, the traditional sealed hot channels are complex in construction and cumbersome in installation, and thus cannot meet flexible deployment and elastic adaptation of the new generation of data center computer rooms.

### SUMMARY

Objectives of the present disclosure are to provide a prefabricated data center computer room, which can improve movement efficiency and accuracy of a modular cabinet, to solve a technical problem that the modular cabinet is unable to move efficiently under a prefabricated hot channel structure in existing technologies.

To achieve the above objectives, the present disclosure provides a prefabricated data center computer room, which includes a modular cabinet and a modular channel. The modular channel includes a frame body including a first frame and a second frame, where a preset distance is provided between the first frame and the second frame to form a hot channel. The first frame and the second frame both have a truss structure, and certain spacing is provided between the truss structure and a bottom of the frame body to form a containment area. A plurality of the modular cabinets are provided and arranged side by side in the containment area, which is also internally provided with a guide component. When the modular cabinet comes into contact with the guide component, the guide component provides a friction force to the modular cabinet, such that the modular cabinet moves along the guide component.

As a further improvement of the above technical solutions, the frame body also includes at least four pairs of support rods positioned at four corners of the frame body, respectively. One end of each of the at least four pairs of support rods is connected to the truss structure, and other end of each of the at least four pairs of support rods is placed on ground.

As a further improvement of the above technical solutions, a bottom of each of the at least four pairs of support rods is detachably connected to a support leg, where a first bolt hole site is provided on the support leg.

As a further improvement of the above technical solutions, a bottom of the truss structure is provided with a plurality of second bolt hole sites configured to connect the at least four pairs of support rods.

As a further improvement of the above technical solutions, the guide component at least includes a guide base and a plurality of guide rollers, and each of the plurality of guide rollers is rotatably arranged on the guide base. When the modular cabinet is moved within the containment area, the guide roller comes into contact with a sidewall of the modular cabinet and rotates as the modular cabinet moves to provide the friction force to the modular cabinet.

As a further improvement of the above technical solutions, certain spacing is provided between each pair of the at least four pairs of support rods, where two ends of the guide base are connected to two of the same pair of the at least four pairs of support rods, respectively. When the sidewall of the modular cabinet comes into contact with each of the plurality of guide rollers, the modular cabinet moves along the guide base.

As a further improvement of the above technical solutions, the truss structure at least includes two truss pieces, which are detachable connected to each other.

As a further improvement of the above technical solutions, a reinforcing rod is arranged on each of the two truss pieces to place a cable.

As a further improvement of the above technical solutions, the modular channel also includes baffles, a plurality of baffles are detachably connected to each of opposite sides of the two truss structures, and the plurality of baffles jointly constitute sidewalls of the hot channel.

As a further improvement of the above technical solutions, ends of the two truss structures are connected to form a channel door frame, and a baffle is arranged on the channel door frame, where the baffle covers the channel door frame.

As can be seen from the technical solutions provided by the present disclosure, hot air discharged from the modular cabinet is collected by means of the sealed hot channel, to prevent the hot air from mixing with cold air, and all the hot air is ensured to flow into an air-conditioning return air outlet for cooling. The cooled air is conveyed to an air inlet of the modular cabinet, avoiding rise of supply air temperature due to mixing of the cold air and the hot air inside the data center computer room, such that utilization rate of cooling capacity of an air conditioner is significantly improved, also more heat generated by devices is taken away, there achieving higher energy-saving effects. In this way, a power usage efficiency (PUE) value of the computer room is reduced, and it is ensured that operation and maintenance personnel work in a suitable temperature environment.

Furthermore, the guide component is installed on the modular channel to guide the modular cabinet and increase movement speed of the modular cabinet, thereby improving placement efficiency and accuracy of the modular cabinet.

### BRIEF DESCRIPTION OF THE DRAWINGS

To describe the technical solutions of the embodiments of the present disclosure more clearly, the accompanying drawings required in the description of the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a prefabricated data center computer room according to an embodiment the present disclosure;

FIG. 2 is a schematic structural diagram of a prefabricated data center computer room according to an embodiment the present disclosure; and

FIG. 3 is a schematic structural diagram of a guide component according to an embodiment the present disclosure.

### REFERENCE NUMERALS IN THE ATTACHED DRAWINGS

frame body 10; first frame 101; second frame 102; truss structure 103; support rod 104; support leg 105; support connecting plate 106; reinforcing rod 107; baffle 108; modular cabinet 20; guide component 30; guide base 31; and guide roller 32.

### DETAILED DESCRIPTION

To make the objectives, technical solutions and advantages of the present disclosure clearer, the embodiments of the present disclosure will be further described in detail below with reference to the accompanying drawings. The terms such as “upper”, “above”, “lower”, “below”, “first end”, “second end”, “one end”, “other end” as used herein, which denote spatial relative positions, describe the relationship of one unit or feature relative to another unit or feature in the accompanying drawings for the purpose of illustration. The terms of the spatial relative positions may be intended to include different orientations of a device in use or operation other than the orientations shown in the accompanying drawings. For example, a unit that is described as “below” or “under” other units or features will be “above” the other units or features when the device in the accompanying drawings is turned upside down. Thus, the exemplary term “below” may encompass both the orientations of above and below. The device may be otherwise oriented (rotated by 90 degrees or facing other directions) and the space-related descriptors used herein are interpreted accordingly.

In addition, terms “installed”, “arranged”, “provided”, “connection”, “sliding connection”, “fixed”, and “sleeved” should be understood in a broad sense. For example, the “connection” may be a fixed connection, a detachable connection or integrated connection, a mechanical connection or an electrical connection, a direct connection or indirect connection by means of an intermediary, or internal communication between two apparatuses, elements, or components. The specific significations of the above terms in the present disclosure may be understood in the light of specific conditions by persons of ordinary skill in the art.

The present disclosure provides a prefabricated data center computer room, which is described in detail below. It is to be noted that description order of the following embodiments does not limit preferred order of the embodiments of the present disclosure. In the foregoing embodiments, description of various embodiments may be focused on differentially, and reference may be made to related descriptions of other embodiments for a part not expatiated in a certain embodiment.

With the rapid development of information and communication industries, integration level and heat density of electronic devices are increasing. Sealed hot channels used in traditional data centers can no longer meet needs of contemporary data center computer rooms. At present, there are mainly two manners of installing the sealed hot channel of a data center. The first one is a fixed installation, that is, a bottom of the hot channel is fixed on a top of a modular cabinet. The hot channel cannot be installed unless the modular cabinet has been installed. In the first manner, construction period is longer, and the modular cabinet cannot be moved flexibly after the installation of the hot channel, making it difficult to meet flexible deployment and elastic adaptation of the new generation of data centers. The second one is a hanging installation, that is, the hot channel is installed by means of a floor slab in a hanging way. The second manner is complex and difficult in construction, and is demanding for technological requirements.

Therefore, most of the existing data center computer rooms use prefabricated hot channels to achieve physical isolation and directional flow of air inside the data center computer rooms, such that cooling capacity provided by precision air conditioners is fully utilized to improve return air efficiency of the air conditioners, thus achieving effects of energy conservation and consumption reduction.

However, the existing prefabricated hot channels are affected by their frame structures, which limits placement positions of the modular cabinets. Thus, it is not convenient for operation and maintenance personnel to operate when moving the modular cabinets, making it difficult to efficiently move the modular cabinets to designated positions.

For this reason, embodiments of the present disclosure provide a prefabricated data center computer room, which can, by arranging a guide component to guide movement of the modular cabinet, improve movement efficiency and accuracy of the modular cabinet, to solve a technical problem that the modular cabinet is unable to move efficiently under the prefabricated hot channel structure in existing technologies. Detailed descriptions are made below, respectively.

The technical solutions in the embodiments of the present disclosure will be described clearly and completely below in conjunction with the accompanying drawings. Apparently, the embodiments described in the present disclosure are some but not all of the embodiments of the present disclosure. All other embodiments obtained by those skilled in the art based on the embodiments of the present disclosure without creative efforts shall fall within the protection scope of the present disclosure.

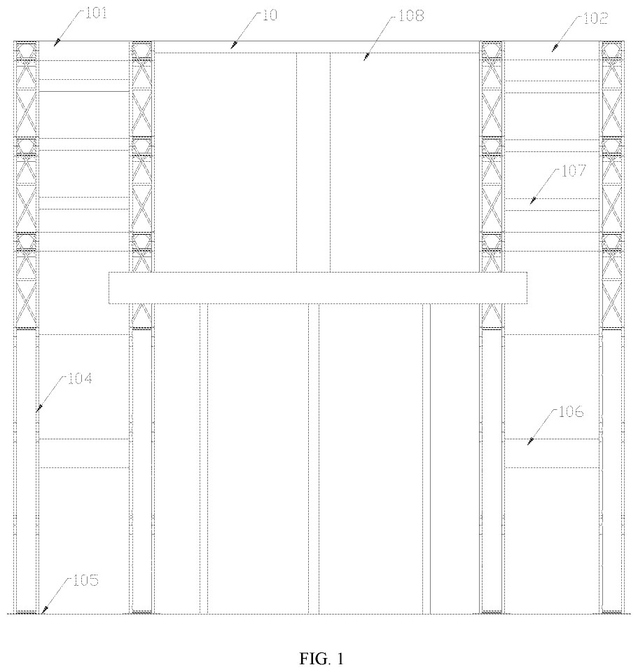

Referring to FIG. 1, a prefabricated data center computer room includes a modular cabinet 20 and a modular channel. The modular channel includes a frame body 10, which includes a first frame 101 and a second frame 102, where a preset distance is provided between the first frame 101 and the second frame 102 to form a hot channel. The first frame 101 and the second frame 102 both have a truss structure 103, and certain spacing is provided between the truss structure 103 and a bottom of the frame body 10 to form a containment area. A plurality of the modular cabinets 20 are provided, and the plurality of modular cabinets 20 are arranged side by side in the containment area, which is also internally provided with a guide component 30. When the modular cabinet 20 comes into contact with the guide component 30, the guide component 30 provides a friction force to the modular cabinet 20, such that the modular cabinet 20 moves along the guide component 30. In this way, a direction of movement of the modular cabinet 20 is guided by means of the guide component 30, which can effectively avoid a situation where the modular cabinet 20 deviates from a route during movement and thus is placed improperly.

In an implementable embodiment, the frame body 10 also includes at least four pairs of support rods 104 positioned at four corners of the frame body 10, respectively. One end of each of the at least four pairs of support rods 104 is connected to the truss structure 103, and other end of each of the at least four pairs of support rods 104 is placed on ground. In practical applications, there is a certain distance between two support rods 104 belonging to the same pair to expand a support range, thereby improving support stability of the truss structure 103.

In an implementable embodiment, a bottom of each of the at least four pairs of support rods 104 is detachably connected to a support leg 105, where a first bolt hole site is provided on the support leg 105. The support leg 105 can be connected to a bolt through the first bolt hole site and can be connected to the ground through the bolt to achieve fixation of the frame body 10. Specifically, the bolt can adopt a pre-embedded structure to improve fixation strength.

Further, a bottom of the truss structure 103 is provided with a plurality of second bolt hole sites configured to connect the at least four pairs of support rods 104. In this way, the truss structure 103 can be connected to the support rod 104 through the second bolt hole site. During the construction period, stability and safety of the frame body 10 is ensured during installation by increasing number of the support rods 104. In addition, the support rods 104 can be removed when the modular cabinet 20 is placed in the containment area to avoid adversely affecting the placement of the modular cabinet 20.

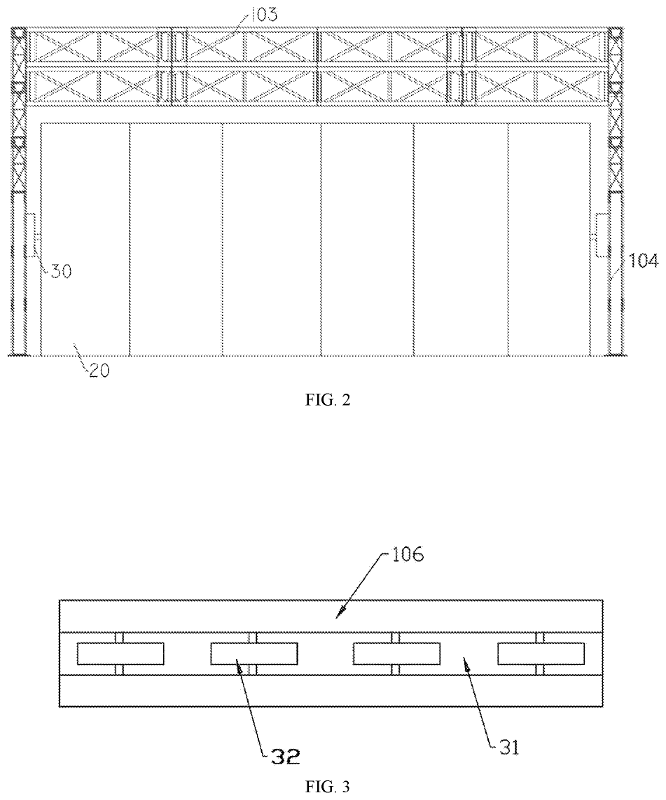

As shown in FIG. 2 and FIG. 3, in an implementable embodiment, the guide component 30 at least includes a guide base 31 and a plurality of guide rollers 32, and each of the plurality of guide rollers 32 is rotatably arranged on the guide base 31. When the modular cabinet 20 is moved within the containment area, the guide roller 32 comes into contact with a sidewall of the modular cabinet 20 and rotates as the modular cabinet 20 moves to provide the friction force to the modular cabinet 20. After the sidewall of the modular cabinet 20 comes into contact with the outermost guide roller 32, the guide roller 32 rolls along the direction of movement of the modular cabinet 20. In this case, the sidewall of the modular cabinet 20 will come into contact with rest of the guide rollers 32 in sequence. That is, the modular cabinet 20 moves along an arrangement direction of the guide rollers 32. In this way, during the movement of the modular cabinet 20, a rolling friction force provided by the guide rollers 32 effectively increase movement speed. Furthermore, the plurality of guide rollers 32 may guide the direction of movement of the modular cabinet 20, such that the modular cabinet 20 can be placed in a designated position. In this way, by positioning the modular cabinet 20 near the support rod 104, positions of rest of the modular cabinets 20 can also be determined.

Further, two support rods 104 belonging to the same pair are connected through a support connecting plate 106, the guide base 31 is arranged on the support connecting plate 106, and two ends of the guide base 31 are connected to the two support rods 104 belonging to the same pair, respectively. The support connecting plate has a certain length, thus when the sidewall of the modular cabinet 20 comes into contact with the guide roller 32, the modular cabinet 20 can move along the guide base 31.

In practical applications, the length of the support connecting plate 106 is equal to a width of the truss structure 103. In this way, when the modular cabinet 20 moves to a tail end of the guide base 31, hot air generated by the modular cabinet 20 during operation can enter the hot channel and then is sucked in by the air conditioner to continue a next air cycle.

In an implementable embodiment, the truss structure 103 at least includes two truss pieces, which are detachable connected to each other. Specifically, the two truss pieces are stacked in a top-and-bottom structure to improve overall stability.

In an implementable embodiment, a reinforcing rod 107 is arranged on each of the two truss pieces to place a cable. Specifically, the reinforcing rod 107 is provided with at least three layers to place cables in multiple connection directions. Further, the reinforcing rod 107 may be detachable, facilitating adjustment of distances between a plurality of reinforcing rods 107, and changing number of the corresponding reinforcing rods 107 according to number of the cables. Still further, a hole is provided on the reinforcing rod 107 to fix cable organizers.

In an implementable embodiment, the modular channel also includes baffles 108, a plurality of baffles 108 are detachably connected to each of opposite sides of the two truss structures 103, and the plurality of baffles 108 jointly constitute sidewalls of the hot channel. Ends of the two truss structures 103 are connected to form a channel door frame, and the baffle 108 is arranged on the channel door frame, where the baffle 108 covers the channel door frame to constitute a channel door. In this way, the hot channel is sealed by arranging the channel door, which can effectively prevent accumulation of dusts inside the hot channel from adversely affecting use, thereby reducing frequency of cleaning and maintenance. Further, a door handle is arranged on the channel door, such that the operation and maintenance personnel can get in or out of the hot channel.

Because the hot channel is sealed, airflow inside the data center flows out from a rear side of the cabinet and then wholly returns to a data center air conditioning room through a return air outlet above the hot channel. In this way, it is avoidable mixing of cold air and hot air, which cannot flow back to a cold channel, thus improving refrigeration efficiency of the data center.

In an implementable embodiment, a plurality of channel adjusting plates are installed inside the hot channel to separate the plurality of modular cabinets 20, avoiding friction damage and poor heat dissipation effects caused by closer distance between the modular cabinets 20. By adjusting positions of the channel adjusting plates, the distance between two channel adjusting plates or between the channel adjusting plate and the channel door can be changed. Thus, positions of the channel adjusting plates can be changed according to sizes of the modular cabinets 20, making it easier to store and install the modular cabinets 20 of different volumes, and also facilitating subsequent transformation and reconstruction of the modular channel.

To further increase speed and efficiency of air flow, an air-exhausting apparatus may be arranged on the rear side of the modular cabinet 20 or on the truss structure 103 to accelerate flow of the hot air into the hot channel, thereby improving heat dissipation efficiency. The air-exhausting apparatus may be an exhaust fan or air extractor, etc.

It is to be noted that both the frame body 10 and the reinforcing rod 107 are prefabricated in a factory according to requirements. After the prefabrication, the modular channel is transported to the site for rapid deployment. In the site, it is only required to connect the support leg 105 to the ground, and other parts are lifted and put into use, thereby improving construction efficiency of the computer room, saving construction cycles and design costs. Furthermore, adverse effects caused by future transformation of the data center are taken into full consideration to facilitate expansion and renovation.

As can be seen from the technical solutions provided by the present disclosure, the hot air discharged from the modular cabinet 20 is collected by means of the sealed hot channel, to prevent the hot air from mixing with the cold air, and all the hot air is ensured to flow into the air-conditioning return air outlet for cooling. The cooled air is conveyed to an air inlet of the modular cabinet 20, avoiding rise of supply air temperature due to mixing of the cold air and the hot air inside the data center computer room, such that utilization rate of cooling capacity of the air conditioner is significantly improved, also more heat generated by devices is taken away, there achieving higher energy-saving effects. In this way, a power usage efficiency (PUE) value of the computer room is reduced, and it is ensured that the operation and maintenance personnel work in a suitable temperature environment.

Furthermore, the guide component 30 is installed on the modular channel to guide the modular cabinet 20 and increase movement speed of the modular cabinet 20, thereby improving placement efficiency and accuracy of the modular cabinet 20.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A prefabricated data center computer room, comprising a modular cabinet and a modular channel; wherein
the modular channel comprises a frame body comprising a first frame and a second frame, a preset distance being provided between the first frame and the second frame to form a hot channel;
the first frame and the second frame both have a truss structure, a certain spacing being provided between the truss structure and a bottom of the frame body to form a containment area, a plurality of the modular cabinets being provided, and the plurality of modular cabinets being arranged side by side in the containment area; and
a guide component is further arranged inside the containment area, and when the modular cabinet comes into contact with the guide component, the guide component provides a friction force to the modular cabinet, such that the modular cabinet moves along the guide component.

2. The prefabricated data center computer room according to claim 1, wherein the frame body further comprises at least four pairs of support rods positioned at four corners of the frame body, respectively; and
one end of each of the at least four pairs of support rods is connected to the truss structure, and other end of each of the at least four pairs of support rods is placed on ground.

3. The prefabricated data center computer room according to claim 2, wherein a bottom of each of the at least four pairs of support rods is detachably connected to a support leg; and
a first bolt hole site is provided on the support leg.

4. The prefabricated data center computer room according to claim 3, wherein a bottom of the truss structure is provided with a plurality of second bolt hole sites configured to connect the at least four pairs of support rods.

5. The prefabricated data center computer room according to claim 4, wherein the guide component at least comprises a guide base and a plurality of guide rollers, each of the plurality of guide rollers being rotatably arranged on the guide base; and
when the modular cabinet is moved within the containment area, the guide roller comes into contact with a sidewall of the modular cabinet and rotates as the modular cabinet moves to provide the friction force to the modular cabinet.

6. The prefabricated data center computer room according to claim 5, wherein certain spacing is provided between each pair of the at least four pairs of support rods, two ends of the guide base being connected to two of the same pair of the at least four pairs of support rods, respectively; and
when the sidewall of the modular cabinet comes into contact with each of the plurality of guide rollers, the modular cabinet moves along the guide base.

7. The prefabricated data center computer room according to claim 1, wherein the truss structure at least comprises two truss pieces, and the two truss pieces are detachable connected to each other.

8. The prefabricated data center computer room according to claim 7, wherein a reinforcing rod is arranged on each of the two truss pieces to place a cable.

9. The prefabricated data center computer room according to claim 1, wherein the modular channel further comprises baffles, a plurality of baffles are detachably connected to each of opposite sides of the two truss structures, and the plurality of baffles jointly constitute sidewalls of the hot channel.

10. The prefabricated data center computer room according to claim 9, wherein ends of the two truss structures are connected to form a channel door frame; and
a baffle is arranged on the channel door frame, the baffle being configured to cover the channel door frame.
